(19) United States
(12) Patent Application Publication
(10) Pub. No.: US 2011/0133066 A1
(43) Pub. Date: Jun. 9, 2011

(54) PATTERN INSPECTION DEVICE AND METHOD

(76) Inventors: Mari Nozoe, Hino (JP); Taku Ninomiya, Hitachinaka (JP)

(21) Appl. No.: 13/059,540

(22) PCT Filed: Sep. 14, 2009
(86) PCT No.: PCT/JP2009/066464

§ 371 Date: Feb. 17, 2011

(30) Foreign Application Priority Data
Sep. 16, 2008 (JP) 2008-235847

(51) Int. Cl. H01J 37/26; G12B 13/00; G01N 23/22

(52) U.S. Cl. 250/252.1; 250/310

(57) ABSTRACT

An inspection apparatus and method are provided capable of suppressing electron beam focus drifts and irradiation-position deviations caused by sample surface charge-up by irradiation of an electron beam during micropattern inspection to thereby avoid false defect detection and also shorten an inspection time. The apparatus captures a plurality of images of alignment marks provided at dies, stores in a storage device deviations between the central coordinates of alignment mark images and the coordinates of the marks as a coordinate correction value, measures heights at a plurality of coordinates on the sample surface, captures images of the measured coordinates to perform focus adjustment, saves the relationship between such adjusted values and the sensor-measured heights in the storage as height correction values, and uses inspection conditions including the image coordinate correction values saved in the storage and the height correction values to correct the image coordinates and height of the sample.

### RELATED APPLICATIONS

This application is the U.S. National Phase under 35 U.S.C. §371 of International Application No. PCT/JP2009/066464, filed on Sep. 14, 2009, which in turn claims the benefit of Japanese Application No. 2008-235847, filed on Sep. 16, 2008, the disclosures of which applications are incorporated by reference herein.

### TECHNICAL FIELD

The present invention relates to an inspection apparatus and inspection method for use in fabrication processes of substrates having fine patterns, such as semiconductor devices, lithography masks, and liquid crystal substrates.

### BACKGROUND ART

Upon explanation of a fine pattern inspection apparatus and method, an explanation will here be given of micro-pattern inspection in the fabrication process of a semiconductor device as one example. Since the same principle is also applicable to lithography masks, liquid crystal display panels, and the like there are no difficulties in application of the invention stated in this example.

Semiconductor devices are manufactured by repeating the transfer of a circuit pattern onto a semiconductor wafer by lithography, etching into a desired three-dimensional shape, and the like. In these fabrication processes, the quality of a fabrication processing result and the generation of particles greatly affect the yield of semiconductor devices. Thus, it is important to detect such defect generation and abnormality by inspection at an early time or in advance and feed back a detection result to fabrication processes in such a way as to prevent the occurrence of failures and irregularities.

As apparatus for inspecting defects existing in micropatterns on semiconductor wafers, an inspection device which emits light to detect reflected light is conventionally known. However, since the resolution of such inspection device depends upon the wavelength of light, it becomes unable to cope with the trend of miniaturization of patterns, resulting in restriction of the application thereof. In order to keep up with the pattern miniaturization, an inspection device which emits an electron beam in place of the light is developed and put into practical use. This is the one that utilizes electron microscope technologies, which detects a secondary signal generated by irradiating the electron beam onto a sample, such as a semiconductor wafer, and converts to an image. As the secondary signal, there are secondary electrons which are relatively low in energy and back scattering electrons higher in energy than the former. A method for detecting respective ones in a separately divided way has also been put into practical use.

The electron beam is irradiated onto a semiconductor wafer after having been reshaped by electron lenses into a narrow beam. Accordingly, in order to achieve the imaging of a desired size of region, the electron beam is deflected by deflectors to scan a top surface of the semiconductor wafer for synchronizing a deflection signal with the sampling clock of a secondary signal detector to thereby perform image conversion, thus making it possible to specify a change with time of an electron beam-irradiated position.

The inspection is executed by comparison calculation processing for finding, after having completed the imaging of a target object, a difference between two images of the same pattern by using the fact that semiconductor devices, i.e., dies, have the same pattern and that a single die contains cells with repetition of the same pattern, such as memory mats, and for extracting a pixel with difference as a defect candidate.

Whereas semiconductor wafers have a diameter of approximately 300 millimeters, the width of a micropattern to be imaged falls within a range of from about 0.1 micrometer to 2 nanometers. On the other hand, when the inspection is performed, it is important where in a semiconductor wafer is being irradiated by the electron beam, i.e., the coordinate accuracy. While a semiconductor wafer which is different per inspection is mounted by either manpower or machine conveyance on a sample support table that is provided in the inspection device, the wafer's setting position with respect to the sample table does not become constant in a strict sense due to the presence of a conveyance error. Hence, traditionally, in inspection devices using electron beam, the point of origin with respect to an inspection device's coordinate system is determined before inspection by means of an alignment mark(s) provided in advance on a semiconductor wafer for the calibration use, thereby a rotation from an ideal wafer setting position and a height correction value are obtained. The height correction value is typically calculated by comparing together an in-focus position which is obtainable using an electron ray image of a standard sample and a measurement value of an optical height sensor with respect to the same standard sample. Traditionally, these correction values of the rotation and height are determined in conformity with the optical conditions of an electron beam to be irradiated onto wafers. And, at the time of inspecting the semiconductor wafer that is a product, a stage position measurement value, an electron beam deflection signal, and a sampling clock for detection of the secondary signal are used to make it possible to specify the coordinates of the imaged object. When the stage position exhibits a variation, it is adjusted by correcting the electron beam deflection amount so as to ensure that the electron beam is irradiated at a desired position.

However, in real semiconductor wafers, the pattern layout is different on a per-product basis; so, the alignment mark position is disparate, causing deviation to take place in the correction value of the rotation. In addition, material, difference in level, in-plane uniformity of semiconductor wafer, and semiconductor wafer warpage state are different at respective fabrication process steps; thus, deviation also occurs in the height correction value. Especially at positions in close proximity to the outer periphery of a semiconductor wafer, the doneness in fabrication process readily becomes uneven so that warpage is generated, causing the height to vary. As a result, only with the correction value that is set up by the calibration-use semiconductor wafer, the focus of the electron beam is drifted.

Additionally, depending on semiconductor wafer materials, an electrical charging phenomenon takes place due to the irradiation of an electron beam; so, the electron beam's focus can drift or the beam irradiation position at the time of deflection can deviate due to the non-uniformity of an electric field distribution created on the surface of a semiconductor wafer. For example, when the surface is covered with a material of silicon oxide film, this deviation tends to increase in quantity. Once the electron beam's irradiation position and focus point drift, it is possible to happen that pattern position deviation is falsely detected as a defect in comparison inspection for comparing the same patterns together. Alternatively, when comparing images of different focus states with each other, amounts of imaged target pixels are different from each other even though patterns are the same so that it is possible to happen that this different pixel part is falsely detected as a defect. Further, once the focus drifts, the image contrast decreases, resulting in a decrease in sensitivity of defect detection.

As remedies for the above-stated focus drift, a technique for correcting the focus based on a actual focus obtained from an image and a reference value (for example, see Patent Literature 1) and a technique for obtaining a drift of focus of a specific region to determine a correction value (e.g., see Patent Literature 2) are known. Additionally, as a remedy for the position deviation of a beam-irradiated position, a technique for obtaining, in order to prevent position deviation of a primary electron beam-irradiated position occurring due to the electrical charge to be accumulated on a wafer as inspection progresses, a deviation quantity of such beam irradiation position from an image between neighboring dies as obtained in the process of executing the inspection and for performing correction (e.g., see Patent Literature 3) is known.

### CITATION LIST

### Patent Literatures

Patent Literature 1: JP-A-2006-332296
Patent Literature 2: JP-A-2007-281084
Patent Literature 3: JP-A-2003-031629

### SUMMARY OF INVENTION

### Technical Problem

In apparatus employing a secondary particle image obtainable by irradiation of a primary electron beam (referred to hereinafter as the electron beam apparatus), the above-noted secondary particle image is captured, in many cases, by executing either pre-charging or pre-dosing with respect to an object onto which the primary electron beam is to be irradiated (such as a semiconductor wafer, lithography mask, liquid crystal substrate, or the like). Alternatively, even when the pre-charging is not performed, the charge-up voltage on a wafer exhibits non-uniformity in the plane of a wafer surface because the electrostatic charge state of a to-be-irradiated object is varied by irradiation of the primary electron beam.

In conventional electron beam devices, the inspection condition of the above-stated irradiation object has been set up in accordance with a preset recipe; the correction values of the focus drift and position deviation are determined pursuant to optical conditions of the primary electron beam to be irradiated onto wafers (for example, an acceleration voltage, beam current value, etc.), and are set up by being read out of an optical condition database in accordance with the primary electron beam's optical conditions which were set in recipes.

However, since the above-stated charge-up non-uniformity occurring on the primary electron beam-irradiated object varies with pre-charge conditions and further on a per-wafer basis, corrections of focus drift and position deviation are not fully conducted by setting up the focus drift and position deviation correction values with respect to the optical conditions of the primary electron beam only.

Additionally, warpage always remains at a wafer that is held on the sample support table and the quantity of such residual warpage is variable on a per-wafer basis. As the wafer's charge-up voltage varies depending on relative height from the wafer, the focus drift correction value that is obtained using a standard sample will not coincide in a precise sense with a focus drift correction value with respect to a wafer which is actually flown in the inspection process.

Accordingly, in the prior art, there has been a problem which follows: execution of the inspection while leaving the position deviated and focus drifted, especially at an outer circumference of a wafer or else, would result in false detection of non-defective portions and/or a decrease in sensitivity. In addition, a correction map for every inspection session in units of respective semiconductor wafers must be created, resulting in an increase in length of an inspection time.

An object of the present invention is to provide an inspection apparatus and inspection method capable of suppressing electron beam's focus drift and irradiation position deviation caused by the charge-up phenomenon on a sample surface occurring due to electron beam irradiation in the inspection of micropatterns to thereby prevent the false detection of a defect and also shorten the inspection time period.

### Solution to Problem

The inventors of this invention have focused attention on the fact that either the in-plane uniformity or the warpage state of an object onto which the primary electron beam is to be irradiated, such as a material, step-like difference, or the like, is almost the same as long as a step of the fabrication process of the to-be-irradiated object (i.e., which one of a series of fabrication process steps that the product has experienced) is the same. If it is an irradiation target object obtained at the same step of the fabrication process, the inspection conditions must be the same; thus, the pre-charge conditions are also the same. Therefore, it is permissible to presume that the uniformity of charge-up being created on the irradiation object also is approximately the same.

Consequently, this invention solves the aforementioned problem by calculation of the above-stated focus drift correction value and position deviation correction value with use of the real irradiation object at the inspection recipe preparation stage. The calculation of these focus drift and position deviation correction values is not the one that is executed completely independently of conventional focus correction and alignment; for the calculation of the focus drift correction value, the focusing condition information obtained by conventional focus correction is employed; for the calculation of the position deviation correction value, information as to the point of origin of a coordinate system, magnification information, and rotation information which are obtained in conventional alignment are used.

It should be noted that in this description hereinafter, the above-noted focus drift will be called the “focus shift” in the sense that it is a drift from a focusing condition obtained by execution of focus tuning using a standard sample; similarly, the above-noted position deviation will be called the “position shift” in the meaning of a position deviation in the plane of a wafer surface which can also take places even after having performed the wafer alignment. These focus shift correction value and position shift correction value thus obtained are stored in a storage means as a recipe. For those primary electron beam-irradiated objects to which the same recipe is applied, the recipe will be read out of the aforementioned storage means for application thereto.

The calculation of the focus shift correction value and position shift correction value is executed by an image processing device which performs processing of an image of secondary particles generated due to irradiation of the primary electron beam.

### Advantageous Effects of Invention

According to this invention, it is possible to suppress the electron beam's focus drift and irradiation position deviation which are caused by the charge-up phenomenon on a sample surface occurring due to electron beam irradiation in the inspection of micropatterns, thereby to prevent the false detection of a defect. It is also possible to provide an inspection device and inspection method capable of shortening the inspection time.

### BRIEF DESCRIPTION OF DRAWINGS

FIG. 1 is a longitudinal cross-sectional diagram showing a configuration of main part of a semiconductor wafer inspection apparatus using an electron beam.

FIG. 2 is a diagram showing an inspection recipe generation flow.

FIG. 3 is a plan view of a sample holder.

FIG. 4 is a sectional diagram of the sample holder.

FIG. 5 is a graph showing a relationship of a height sensor measurement value and a value of an objective lens which becomes in-focus.

FIG. 6 is a plan view of a semiconductor wafer.

FIG. 7 is a screen diagram showing one example of an image at the time of position/focus correction, which is displayed on a display screen.

FIG. 8 is a screen diagram showing one example of an image at the time of position/focus correction, which is displayed on a display screen.

FIG. 9 is a screen diagram showing an example which displays, in thumbnails form, die corner images at seven representative portions after having captured an image for the position shift/focus shift correction use.

FIG. 10 is a screen diagram showing an example which displays, in the same manner as FIG. 9, die corner images that are obtained by control of a primary electron beam based on the position shift/focus shift correction values thus set up.

FIG. 11 is a vertical sectional diagram of a contact hole-formed sample which is one example of an object being inspected.

FIG. 12 is a vertical sectional diagram of a contact hole formed sample which is one example of an object being inspected.

FIG. 13 is a sectional diagram showing a semiconductor wafer structure which less susceptible to charge-up by the electron beam.

FIG. 14 is a flow chart showing an entire operation of an inspection apparatus in accordance with an embodiment 2.

FIG. 15 is a flow chart showing details of main part of FIG. 14.

FIG. 16 is a screen diagram showing one example of an image at the time of test inspection, which is displayed on a display screen.

FIG. 17 is a screen diagram showing one example of an image at the time of test inspection, which is displayed on a display screen.

FIG. 18 is a screen diagram showing one example of an image at the time of test inspection, which is displayed on a display screen.

FIG. 19 is a graph showing a relationship between a semiconductor wafer surface height measurement value measured by a height sensor and a focus condition.

FIG. 20 is a graph showing a relationship between a semiconductor wafer surface height measurement value measured by a height sensor and a focus condition.

FIG. 21 is a screen diagram showing one example of an image at the time of position/focus correction, which is displayed on a display screen.

FIG. 22 is a screen diagram showing one example of an image at the time of position/focus correction, which is displayed on a display screen.

FIG. 23 is a diagram pictorially representing scan stripe capture at the time of generating position shift correction data.

FIG. 24 is a diagram pictorially showing image capture at the time of generating focus shift correction data.

### DESCRIPTION OF EMBODIMENTS

Although in embodiments as set forth below an explanation will be given using a configuration of semiconductor wafer inspection apparatus, the present invention may also be applied to apparatuses other than the inspection apparatus as long as these are electron beam-applying apparatuses or devices which are faced with problems of focus drift or position deviation of image depending upon positions on a target object, such as a pattern length measuring apparatus, review apparatus, and the like. Further, this invention is also applicable to apparatuses of the type using a charged particle beam other than the electron beam such as ion microscopes because those apparatuses which irradiate the charged particle beam onto a target object to capture images are such that an charge-up state of the object inevitably affects the image qualities.

### Embodiment 1

One embodiment of his invention will now be explained below with reference to the drawings.

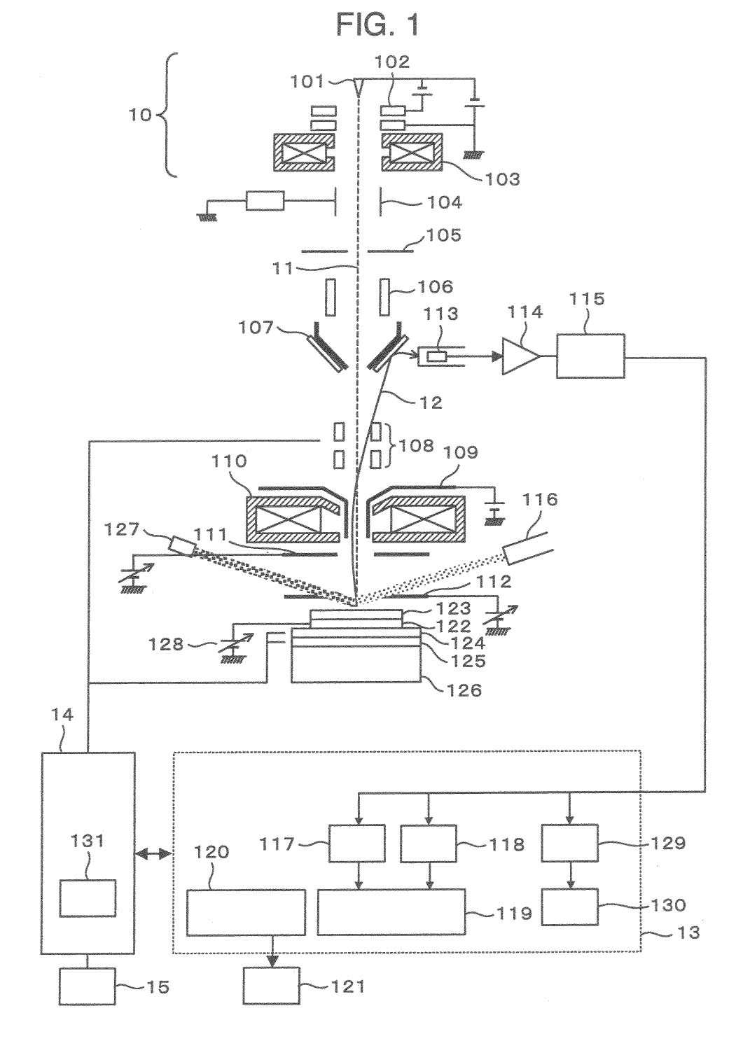

FIG. 1 is a longitudinal cross-sectional diagram showing a configuration of main part of a semiconductor wafer inspection apparatus using an electron beam, wherein the illustration of a vacuum vessel is omitted. The inspection apparatus of this embodiment is generally made up of an electron optical column which irradiates a primary electron beam onto a sample, detects secondary particles generated, and then outputs a detection result as a secondary signal; X-stage and Y-stage for moving in an X-Y plane a sample table that mounts the above-mentioned sample thereon; an image processing unit 13 which executes prespecified calculation processing to the above-mentioned secondary signal; and a control unit 14 which controls respective devices or equipments of the inspection apparatus, such as the above-noted electron optical column, the X-stage 124 or the Y-stage 125, and others.

Although not specifically depicted, the sample table is situated in a vacuum sample chamber, and a spare chamber for conveying a sample into the inspection device is provided through a gate valve so that it lies next to the vacuum sample chamber. Also, within the electron optical column, a potentiometer is equipped for measurement of a voltage on a top surface of a wafer being inspected. The potentiometer is arranged to have a probe, wherein a probe position changes with a wafer surface voltage so that the amount of a change is used to calculate an charge-up quantity. For use as another means for surface potential measurement, there is also equipped a means for varying the landing energy of electrons to capture an electron beam image and for measuring the charge-up quantity based on a change in brightness thereof.

An electron beam 11 emitted by an electron gun 10 within the electron optical column is irradiated onto a sample 123, such as a semiconductor wafer, resulting in generation of secondary particles 12, which is detected by a detector 113 and imaged by the image processing unit 13 so that a magnified image of the sample 123 is displayed on the screen of a display 121.

At the electron gun 10, the electron beam 11 that is produced at an electron source 101 is extracted and accelerated by an extraction electrode 102. The electron beam 11 is reshaped by a condenser lens 103 into a narrow beam. A blanking electrode 104 deflects the electron beam 11 in order to prevent the electron beam 11 from being irradiated onto the sample 123. The electron beam 11 deflected by the blanking electrode 104 is blocked by an aperture 105 from irradiation onto the sample 123. The electron beam 11 is reshaped narrowly by an objective lens 110 and then reaches the sample 123. To perform the imaging of a region with a certain degree of wideness, the electron beam 11 is deflected by a deflector 106 and a scan deflector 108 for being scanned on the sample 123. The scan deflector 108 is configured from an upside scan deflector which controls a deflection range of the primary beam within a relatively wide area and a downside scan deflector which deflects the above-described primary beam within a range narrower than that of the upside scan deflector. The secondary particles 12 generated by irradiation of the electron beam 11 is deflected by a secondary signal deflector 109 to a direction of the detector 113 and then detected by the detector 113. By synchronizing the information of the position and time of a deflection signal of the electron beam 11 with a sampling clock of the detector 113, the coordinates of pixels on the image are determined.

The secondary particles 12 detected by the detector 113 are then amplified by an amplifier 114, converted by an AD converter 115 into a digital signal from an analog signal, and then sent to the image processing unit 13. Image data of a single region is stored in an image memory 117; image data of a region that is next sent is stored in an image memory 118. At a comparison calculation unit 119, the image data being stored in the image memory 117 and the image memory 118 are compared to each other. Image data of a difference therebetween is sent to a defect determination unit 120. Of the difference image data, those pixels having signal amounts greater than or equal to a preset threshold value are extracted as defect candidates. The difference image data is displayed on the screen of the display 121. Additionally, the coordinates of a representative pixel in the defect candidate pixels, e.g., a pixel corresponding to the center of gravity, are stored in a memory of the defect determination unit 120.

Within the image processing unit 13, there are equipped an image memory 129 which stores image data used to calculate position shift correction data and focus shift correction data as will be described later and a dictionary comparison unit 130 which calculates the position shift correction data and the focus shift correction data.

The sample 123 is mounted on the sample holder 122 and fixed thereto. The sample holder 122 is movable in either X-direction or Y-direction with the X-stage 124 and Y-stage 125 on a base 126. The surface height of the sample 123 is measured by a height sensor 127. Applied to the sample holder 122 by a retarding power supply 128 is a retarding voltage for decelerating the electron beam 11. In some cases, electrons are irradiated from a pre-charge unit 116 for controlling a surface voltage of the sample 123. An electrode 111 and electrode 112 are provided between the sample 123 and the objective lens 110 for controlling an electrical field of a surface region of the sample 123 onto which the electron beam 11 is irradiated in such a way that the electric field becomes uniform. For control of respective equipments stated above, a processor of the control unit 14 computes control data and generates control signals; control data are sent to respective equipments. Additionally, within the control unit 14, a database 131 is provided for storage of generated inspection recipes; on the occasion of inspection, the database is referenced and inspection conditions are set up.

Connected to the control unit 14 is an interface unit 15 which has a display which displays a region setup screen for setting an inspection recipe and input devices such as a keyboard or a mouse for entry of inspection parameters.

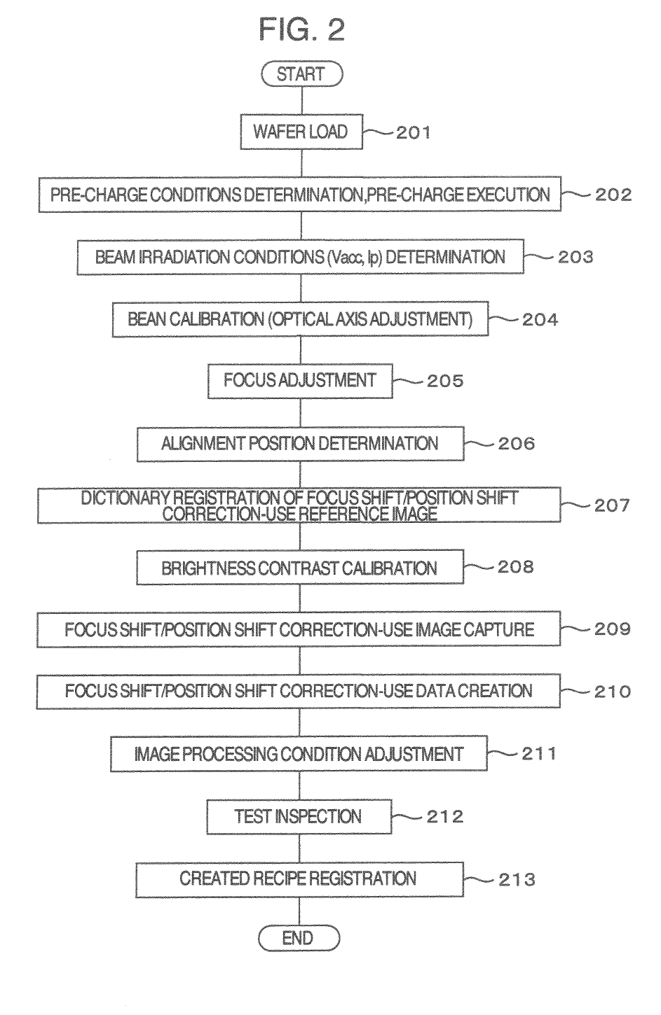

FIG. 2 shows an inspection recipe generation flow. When inspecting a wafer with its inspection recipe being unregistered to the database 131, the inspection recipe generation flow is executed prior to startup of actual inspection.

An apparatus operator loads a semiconductor wafer which is a sample (at Step 201) and sets up pre-charge conditions when the need arises. As previously stated, the pre-charge condition is determined depending upon an inspection object; so, if wafer history information is available which indicates that the wafer of interest is at which one of fabrication steps, the pre-charge conditions can be set. After setup of the pre-charge conditions, pre-charging is executed (Step 202). Thereafter, a surface potentiometer within the apparatus is used to measure a voltage distribution of the sample surface. If the influence on the electron beam is within an allowable range, beam irradiation conditions of the electron beam are determined (Step 203) and, further, optical axis adjustment of the electron beam is performed (Step 204).

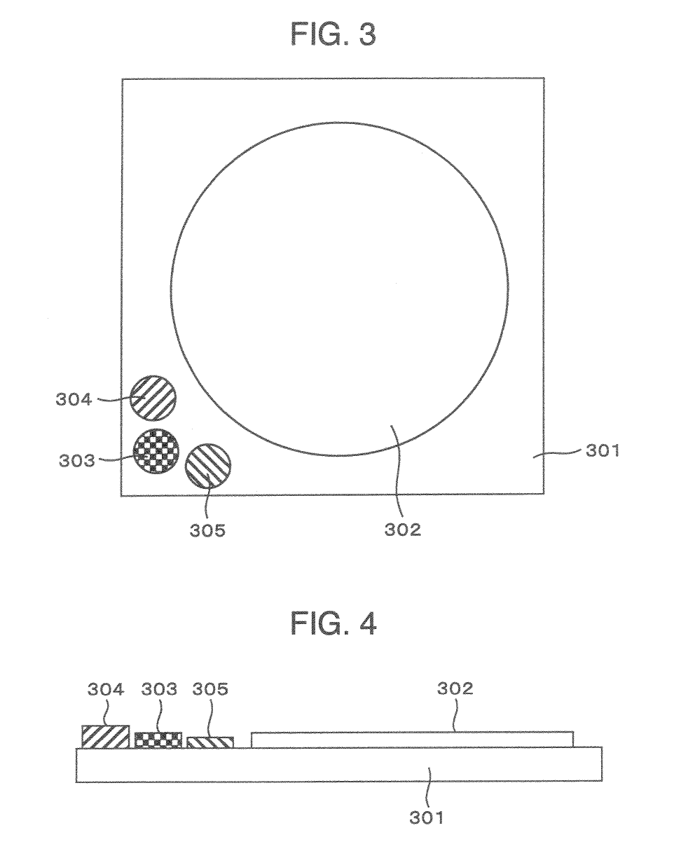

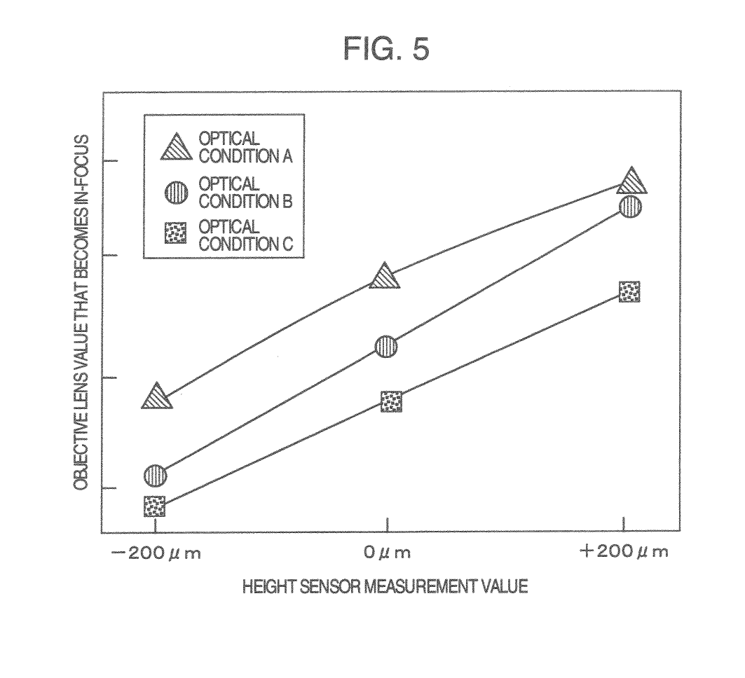

After completion of the beam calibration at Step 204, focus tuning is performed using height calibration pieces which are provided on the sample holder. The focus tuning will be explained in detail by using FIG. 3, FIG. 4, and FIG. 5 below.

FIG. 3 is a plan view of the sample holder and FIG. 4 is a sectional diagram of the sample holder. FIG. 5 is a graph showing a relationship of a height sensor measurement value and a value of an objective lens which becomes in-focus. As shown in FIG. 3 and FIG. 4, a piece A 303 which becomes the same in height as a sample 302 when the sample 302 is mounted on the sample holder 301, a piece B 304 higher than the piece A 303 by a known height value (e.g., 200 micrometers), and a piece C 305 lower than the piece A 303 by a known height value (e.g., 200 micrometers) are provided on the sample holder 301. And, by the height sensor 127 shown in FIG. 1, heights of the piece A 303, piece B 304 and piece C 305 are measured.

Next, regarding a predetermined primary electron beam irradiation condition, e.g., optical condition A, the electron beam is irradiated onto these pieces while changing the excitation condition of the objective lens to thereby plot in the graph shown in FIG. 5 an applied voltage value of excitation condition at the time of coming into focus and a measurement value by means of the height sensor 127. The focusing condition is detected by pickup of a plurality of images based on preceding and proceeding heights with an appropriate focus height being as a reference, i.e., under in-focus condition and out-of-focus condition. This is performed with respect to the optical condition B and optical condition C also, thereby preparing a graph of the relationship as shown in FIG. 5. The processing above is executed by the processor within the control unit 14. By letting the graph be displayed on the screen of the display 121, it is possible to clarify the relationship between the objective lens and the height sensor. Besides, it becomes evident from FIG. 5 that a change in the excitation condition of the objective lens leads to what degree of change the focus exhibits; so, adversely, it is possible for the processor of the control unit 14 to obtain an excitation amount of the objective lens based on the focus correction quantity.

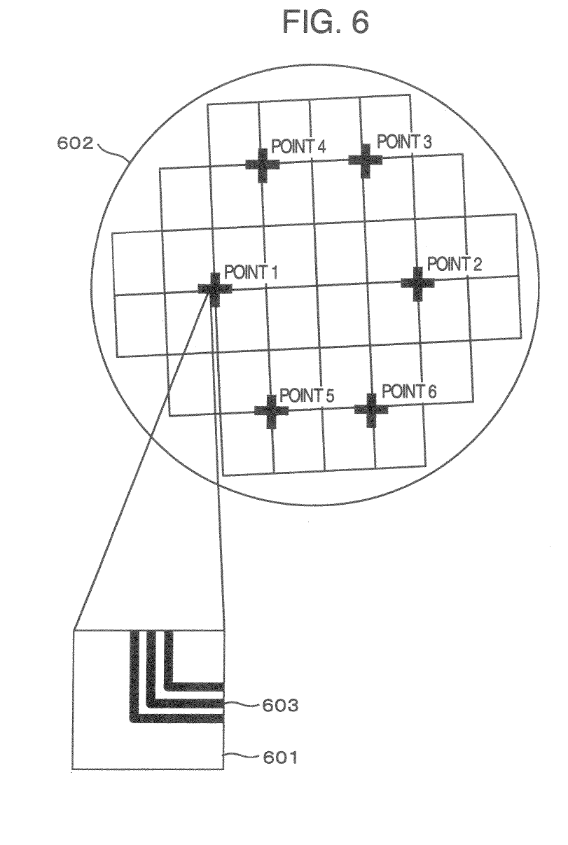

After completion of the focus condition adjustment at Step 205, wafer alignment is executed (at Step 206). The wafer alignment will be explained in detail using FIG. 6 below, FIG. 6 is a plan view of a semiconductor wafer. As shown by a magnified image 601, a die corner 603 of semiconductor wafer 602 is used as an alignment mark. The alignment mark is the one that was formed by an apparatus which is different from the inspection apparatus and thus represents the coordinate system of the alignment mark-forming apparatus. In this example, a point 1, point 2, point 3, point 4, point 5 and point 6 for the alignment use are image-sensed, which are provided at six die corners, for example, and with coordinates of these points as references, a coordinate point of origin of the coordinate system to be used by the image processing unit 13 and control unit 14 is determined. In other words, the alignment mark-composed point of origin of coordinates is forced to coincide with the coordinate point of origin of the coordinate system to be used by the inspection apparatus. Then, a rotation, orthogonality of horizontal and vertical, magnification in X-direction, and magnification in Y-direction of the semiconductor wafer 602 are obtained. Note that when a wafer having no alignment masks provided thereon, adequate patterns within dies on the wafer are used as the alignment marks.

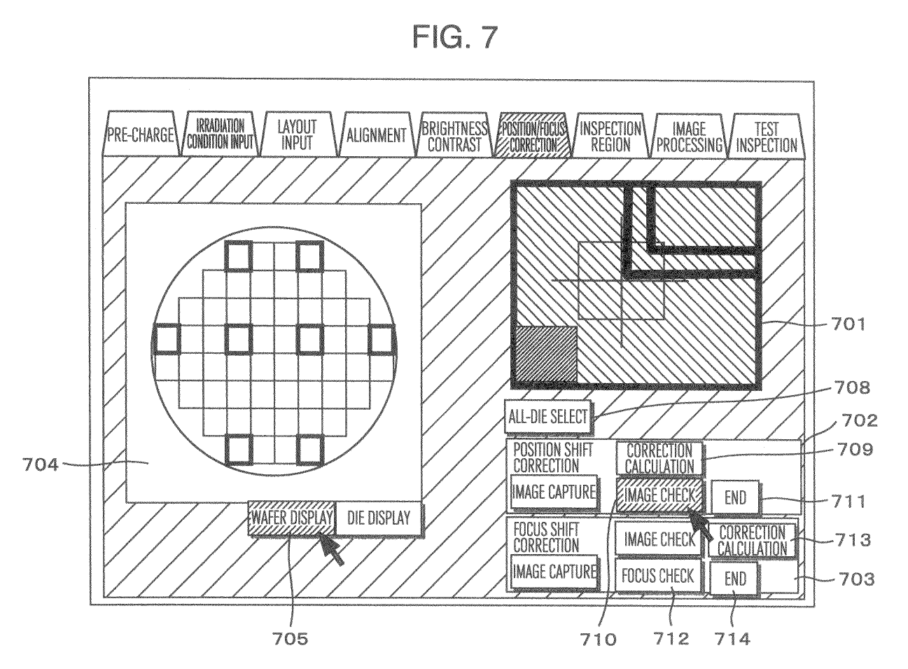

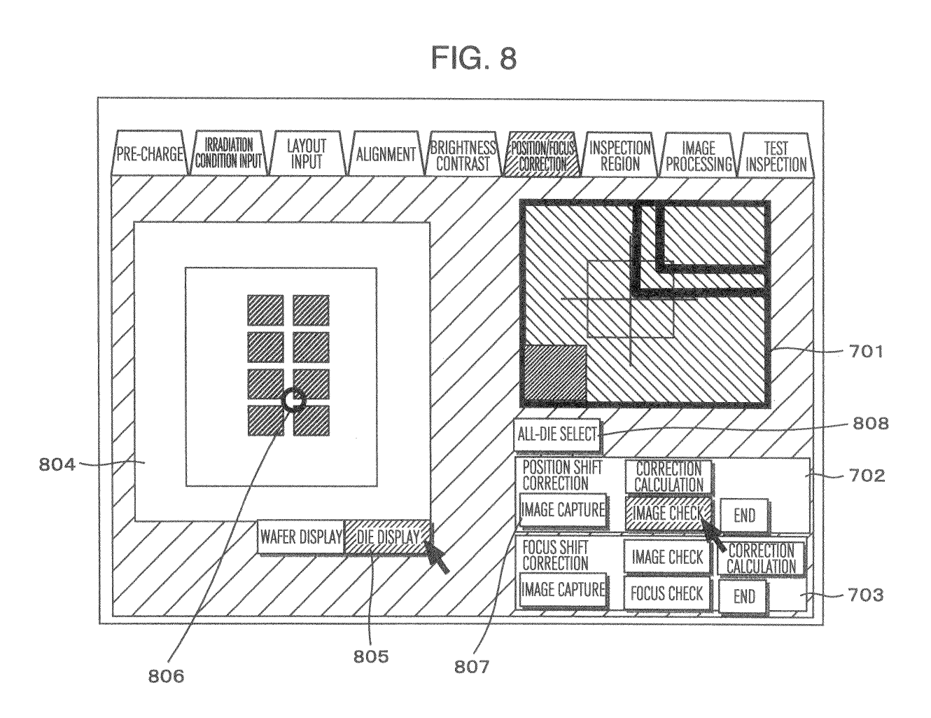

After having executed the wafer alignment, a region which becomes the reference for computing the correction value of the “focus shift” and the correction value of “position shift” as has been explained in the paragraph titled “Solution to Problem” and a region on the wafer for calculation of correction values are set up on the wafer; then, position information of these setup regions is registered to the memory 129 (at Step 207). Hereinafter, the Step 207 will be explained in detail using FIG. 7 and FIG. 8.

FIG. 7 and FIG. 8 are pictorial diagrams of on-screen display images referenced when determining a focus shift correction value and a position shift correction value, which are among a series of setup screens to be referenced by the apparatus operator at the time of generating an inspection recipe. On the right side of FIG. 7 and FIG. 8, a captured image 701 used for the position/focus correction is displayed; in adjacent thereto, a position shift correction menu area 702 and a focus shift correction menu area 703 are displayed. On the left side, for FIG. 7, a schematic diagram 704 of the plan view of the semiconductor wafer is displayed in response to clicking on a tab 705; for FIG. 8, a schematic diagram 804 of a plan view of dies is displayed in response to clicking on a tab 805.

The apparatus operator selects a die for capture of the reference image that is used to compute the focus shift correction value and the position shift correction value by clicking on an appropriate die in the wafer plan-view schematic diagram 704 being displayed on the left side of FIG. 7. The position information of the selected reference image capture die is stored in the memory 129 within the image processing unit 13.

Next, the apparatus operator selects a die for capture of an image used to compute the focus shift correction value and the position shift correction value by performing a click operation on the wafer plan-view schematic diagram 704 in a similar way. This selection can be done with respect to any given die on the wafer. When designating a neighboring die, it is possible, by moving the mouse while holding its left button pushed, to designate a plurality of preferred dies at a time by designating an area. Additionally, upon depression of an all-die select button 708 and 808 indicative of all dies, setting is performed to capture the images of portions of all dies corresponding to a mark 806.

As the real inspection object is an ultrafine pattern formed in a die(s), the image for use in computation of the focus shift and position shift correction values also is required to have its resolution and view-field size equivalent to those of the image used for inspection. Accordingly, an image capture region in a die is selected using the setup screen shown in FIG. 8. A die corner (e.g., see 603 in FIG. 6) is appropriate for use as the portion at which position deviation/focus drift is readily recognized; so, the image capture region inside the die is set up on the die plan-view schematic diagram 804. This setting operation is executed in such a manner that the apparatus operator adds the mark 806 indicative of an image capture position. The processor within the control unit 14 reads the center coordinates of the added marks and transfers to the image processing unit 13. Position information of the intra-die image capture region thus transferred is stored in the memory 129. When the apparatus operator pushes an image capture button 807, the control unit 14 controls the electron optical column to thereby capture an image with an adequate viewing field size which is centered at the above-stated center coordinates and then displays as the image 701 an image of die corner at the display.

Upon completion of the Step 207, the captured image's brightness contrast calibration is executed (at Step 208). The calibration is executed in a way that the apparatus operator adjusts the gain of the amplifier 114 shown in FIG. 1 by means of another setup screen different from that of FIG. 7 or FIG. 8, although its detailed explanation is omitted herein because such is a known technology.

After execution of the Step 208, images are captured which are needed to obtain the focus shift and position shift correction values. This operation is performed in a way that the apparatus operator depresses the image capture button shown in FIG. 7 or FIG. 8 after having set up the region for capture of the images necessary for computation of the focus shift and position shift correction values.

When pushing the image capture button shown in FIG. 7 or FIG. 8, the position information of the intra-die image capture region that was set at Step 207 is expanded with respect to the selected die in a similar way. Such control is permitted because the individual die's internal structure must be the same with respect to all dies on the wafer.

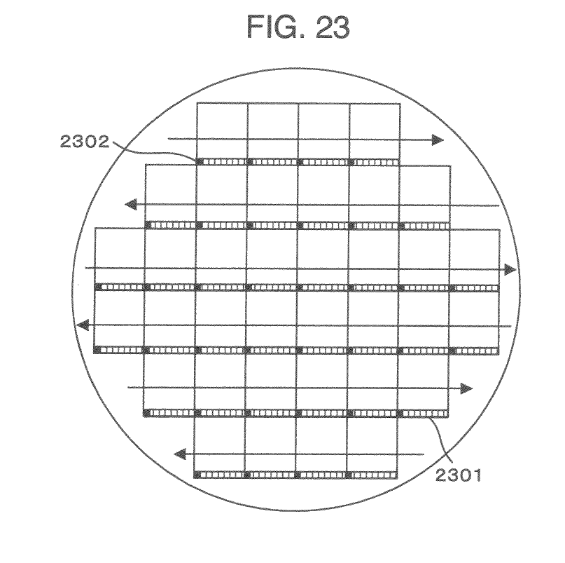

For the case of the position shift correction, a scan stripe 2301 such as shown in-FIG. 23 for example is set based on the above-stated expanded information; then, a deflection width of the scan deflector is set corresponding to the setup scan stripe width (i.e., the length in a direction perpendicular to the traveling direction of the X-Y stage as indicated by an arrow). In addition, a moving amount of the X-Y stage is set corresponding to the length of the scan stripe (i.e., the length in a direction parallel with the moving direction of the X-Y stage as indicated by an arrow). The control unit 14 controls the electron optical column in such a way as to capture an image of the on-wafer region corresponding to the scan stripe being set up while simultaneously reciprocating the X-Y stage continuously in a direction indicated by arrow.

While the primary electron beam is scanned on the scan stripe, a scan stripe image signal is continuously output from a secondary electron detector. Since an enormous capacity of memory is required in order to store an entirety of the scan stripe image data, it is necessary in a practical sense to extract only a requisite part from the scan stripe(s) and store it in the image processing unit 13. The control unit 14 is monitoring the stage motion control information and stage position coordinates at all times during inspection; when a present position of the intra-die image capture region that was set up at Step 207 comes into the viewing field region of the electron optical column, the control unit computes image capture timing information and to-be-captured image size information and then sends them to the dictionary comparison unit 130 within the image processing unit 13. Based on the timing information sent, the dictionary comparison unit 130 performs sampling of image data to be output from the AD converter 115 and stores it in the memory 129. With this processing, the image data needed for the position shift correction is stored within the image processing unit 13.

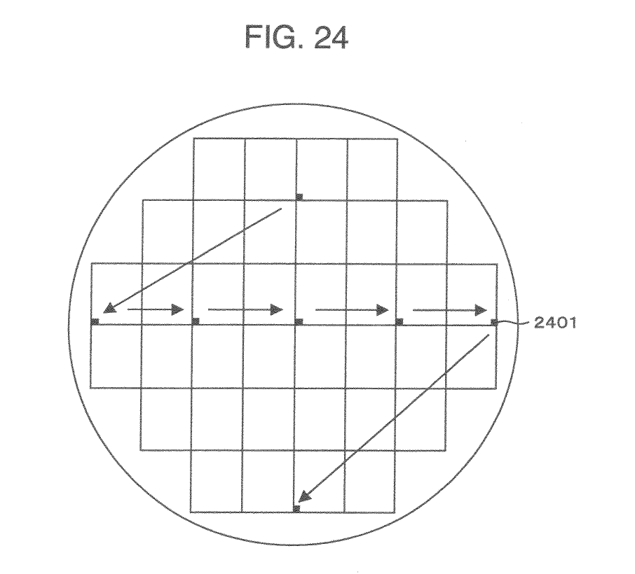

For the case of the focus shift correction, a necessary image is captured based on the above-stated expanded information while moving the stage between a plurality of focus shift correction-use image capture regions 2401 shown in FIG. 24 for example in a step-and-repeat manner. The reason of using the technique for moving the X-Y stage in the step-and-repeat fashion is as follows; in order to calculate focus position conditions, there is a need to capture a plurality of images different in in-focus positions with respect to the same position, and it is difficult to execute this operation by continuous movement of the stage. A stage move amount in the step-and-repeat is controlled by the control unit 14 based on the position information of the position of the intra-die image capture region set up at the Step 207 and the position information of the selected die in a similar way to the case of the position shift correction. Image data obtained at each position is stored in the memory 129 within the image processing unit 13.

Although the above-explained image capturing operation may be performed every time a region is set at Step 207, it is in general more preferable to capture images together at a time at Step 209 because the correction value is obtained with respect to all dies on the wafer in regard to the position shift.

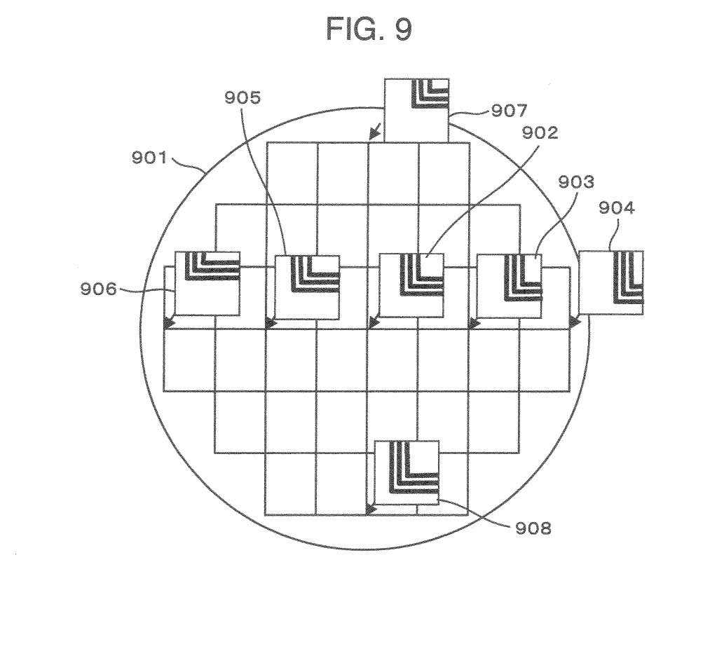

FIG. 9 is a diagram showing images at seven representative portions with respect to the images of a designated region which were captured after execution of the Step 209. The captured images are confirmable on the setup display screen shown in FIG. 7; the images of the designated region captured are displayed in the form of thumbnail images 903 to 908, which are superposed on the semiconductor wafer plan-view schematic diagram 704 shown on the left side of FIG. 7. The reference die that was set up at Step 207 is a die which is placed near the center of a semiconductor wafer 901. When comparing other thumbnail images 903, 904, 905, 906, 907, and 908 with an image 902 of designated region corresponding to the above-mentioned reference die, it is revealed that there is position deviation.

After completion of the Step 209, when the apparatus operator pushes a correction calculation button 709 shown in FIG. 7, the designated region image 902 of the reference die being set up is compared with the image of another setup region, i.e., the image of a region 2302 of FIG. 23 or the image of a region 2401 of FIG. 24, whereby a position deviation amount relative to each setup die is calculated (at Step 210). The position deviation amount can be calculated by executing pattern matching between the reference die and another die's designated region image and by counting the number of pixels of such deviation along with a pixel size at the time of image capture.

On the display screen of FIG. 7, when depressing an image check button 710 and then clicking on any one of the thumbnail images 902, 903, 904, 905, 906, 907, and 908 being displayed on the schematic diagram 704, its magnified image is displayed in an area of the image 701. Further, a position deviation amount is also displayed although not illustrated. In this way, the operator checks with eyes that a calculation result of the position deviation amount is adequate and then pushes a position shift correction end button 711 so that the calculation result is registered to the memory of the control unit 14 as the position shift correction value.

When checking focus drift, the operator pushes the image check button 710 of the position shift correction menu area 702 of FIG. 7 to see an image to be able to confirm focus drift. As previously stated, focus drift tends to take place in peripheral areas of semiconductor wafers; so, the operator makes sure whether focus drift is present or absent in circumjacent die images. When there is an image in which focus drift takes place, the operator pushes a focus check button 712 of the focus shift correction menu area 703 in the state that such die is selected.

When the focus check button 712 is pushed, the control unit 14 causes the X-stage 124 and/or the Y-stage 125 to travel in such a way that the electron beam is again irradiated onto the selected die and, thereafter, controls the electron optical column to capture an image of the setup region within the selected die. The fact that focus drift takes place at this stage means that the use of the image data obtained at Step 209 has failed to enable the intended auto-focusing to function well; so, the operator manually adjusts the focus while simultaneously looking at the image on a focus tuning display screen which is not illustrated. For example, an excitation current value of the objective lens and/or an applied voltage value of a focus tuning-use electrostatic lens are manually adjusted. When a desired image quality is obtained, a focus condition at this time is saved as the focusing condition.

The above-stated focus tuning is performed repeatedly with respect to the selected die; lastly, when depressing a correction calculation button 713, the focusing conditions of respective portions in the surface plane of the semiconductor wafer are interpolated so that a focus shift correction amount is obtained. Finally, by pushing an end button 714, the focus shift correction amount is registered to the memory of the control unit 14. With that, the Step 210 is ended.

At Step 211, image processing conditions used for execution of actual inspection are adjusted, such as filtering treatment to be applied to the image, a threshold value for detection of defects, a method for performing position alignment with its neighboring images, automatic classification conditions for setting defects and/or false detection to prespecified classification codes, and so forth. Thereafter, an image is captured with respect to appropriate stripes on the real wafer, followed by execution of test inspection for verifying whether the inspection is properly executed or not (at Step 212); if a proper operation is verified, the conditions determined at respective steps are stored in the database 131 as an inspection recipe (Step 213).

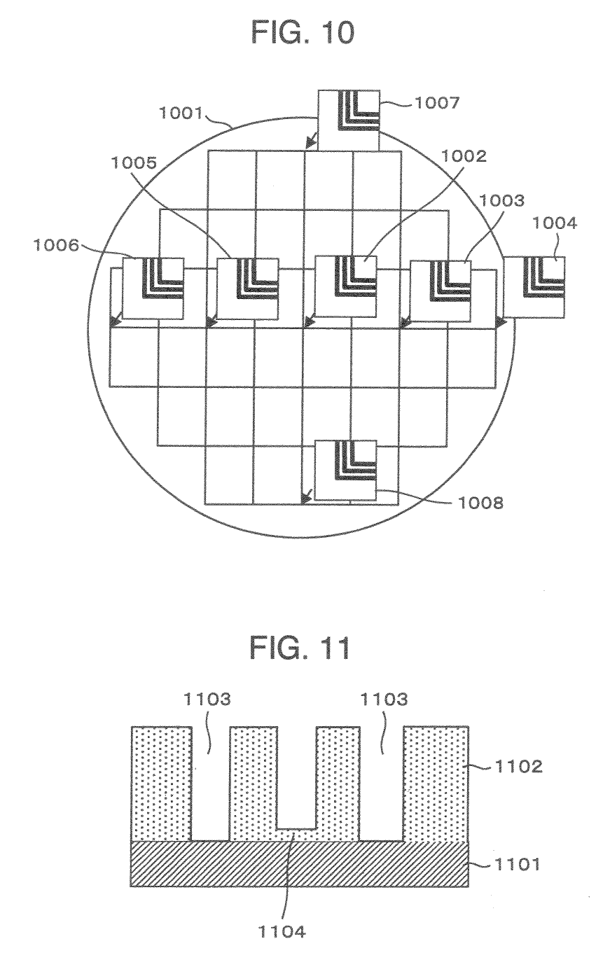

FIG. 10 is a display screen diagram showing an example which thumbnail-displays, as to seven portions in a similar manner to FIG. 9, die corner images which are captured by adjusting the primary electron beam's scan regions and irradiation conditions in accordance with the position shift correction value and focus shift correction values thus obtained. When comparing a die corner image 1002 of a reference die near the center of a semiconductor wafer 1001 with a die corner image 1003, 1004, 1005, 1006, 1007, and 1008 of other dies, it can be seen that the position shift disappears in comparison with the case shown in FIG. 9.

As described above, according to this embodiment, it is possible in the semiconductor wafer inspection to set up an inspection recipe capable of capturing an image(s) without any position deviation or focus drift prior to execution the inspection so that it is possible to detect the generation of defects at an early time and also to obtain the information of defect positions and sizes, which are needed to take corrective actions, at the same time that the inspection is performed, thereby making it possible to shorten the length of a time up to corrective action; as a result, it is possible to improve the fabrication yield of semiconductor devices and also enhance the productivity.

### Embodiment 2

While in the embodiment 1 the inspection device has been explained which is arranged to calculate the position shift and focus shift correction values at the inspection recipe setup stage prior to execution of the inspection, an explanation will be given of an embodiment that is arranged to control the primary electron beam's scan region(s) and irradiation condition(s) while calculating the position shift and focus shift correction values in executing wafer inspection in this embodiment.

Although no extreme position shift or focus shift is supposed to take place in actual inspections when having calculated the position shift and focus shift correction values in the inspection recipe, the actually performed inspection can experience the generation of little position shift or focus shift even if the correction values that were set up in the recipe are used to control the primary electron beam. In other words, although calculating the position shift or focus shift correction value in the recipe is based on the assumption that products are basically the same in the warpage of sample and in the non-uniformity of an charge-up voltage to be formed on wafers after pre-charging if the step of the fabrication process is the same, the reality is such that an exception can occur which fails to satisfy such assumption. Accordingly, it is useful for the apparatus to have its functions of calculating correction values at the time of executing inspection and controlling the primary electron beam while at the same time amending the once-setup correction values at the time of recipe generation.

An inspection apparatus of this embodiment will be concretely explained using drawings hereinafter. Note here that an overall configuration of the inspection apparatus of this embodiment is almost the same as that of the apparatus with the structure shown in FIG. 1; so, FIG. 1 will also be used occasionally in the explanation below. Also note that the same explanation concerning FIG. 1 will not be repeated.

In FIG. 10, FIG. 11, and FIG. 13, a portion of a semiconductor device that is formed on a semiconductor substrate is shown in cross-sectional diagram form as one example of the object under inspection. FIG. 10 and FIG. 11 are vertical sectional diagrams of a sample with contact holes being formed therein. FIG. 10 shows a condition that an insulator film 1102 is formed on a silicon substrate 1101 of the semiconductor wafer, with contact holes 1103 being formed by etching or the like. Due to a certain cause in fabrication process, it sometimes happens that a defective portion 1104 arises at which the bottom of the contact hole 1103 fails to reach the silicon substrate 1101.

FIG. 11 shows a structure wherein an insulator film 1102 is formed on a silicon substrate 1101 of semiconductor wafer by the process shown in FIG. 10, a conductive material plug 1103 is formed in each contact hole, an insulator film 1104 is further formed thereon, and contact holes 1105 are formed by etching or the like. Due to a certain cause in fabrication process, it sometimes happens that a defective portion 1106 arises at which the bottom of the contact hole 1105 fails to reach the conductive plug 1103.

FIG. 13 is a sectional diagram showing one example of the structure of a semiconductor wafer with the electron beam being less subject to effects of charge-up. Shown herein is the structure at a wiring process, wherein an “SiO₂” part 1302 is buried in the silicon substrate 1301, and further a “Poly-Si, W, Wsi” part 1303 and “Si₃N₄” portion 1304 are laid out above the “SiO₂” part.

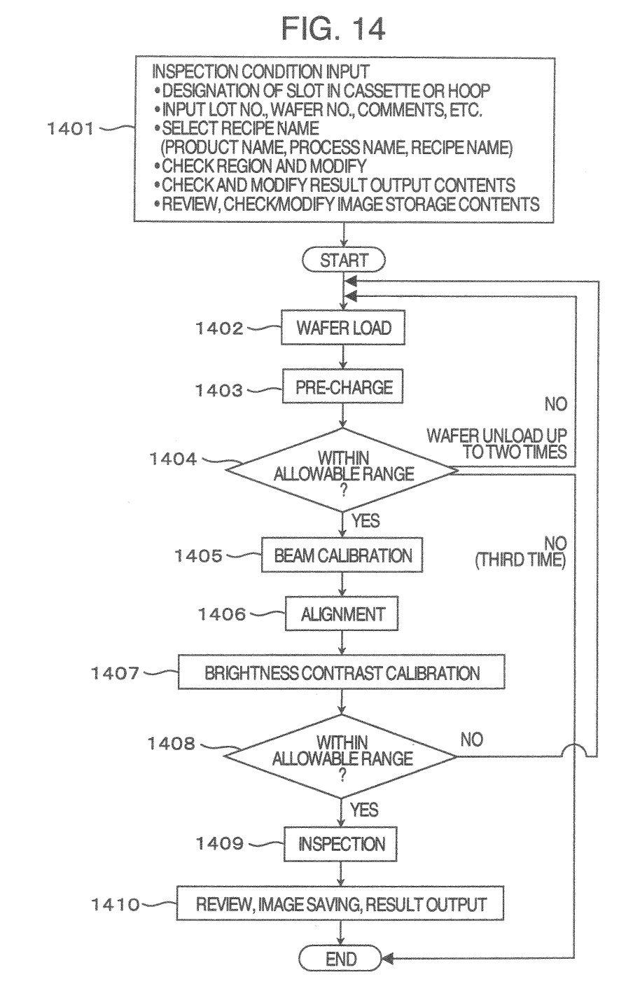

FIG. 14 shows a flow chart of an entire operation of the inspection apparatus of this embodiment. In the inspection apparatus, an inspection recipe setup work is necessary prior to the inspection. At the time of such inspection recipe setup, for example, there are set up an landing energy of electron beam, image magnification factor, i.e., the scan width, and focusing conditions for focusing on a sample surface, and the like. While standard inspection conditions are stored as default values, conditions may be changed by the operator. In this embodiment, it is supposed that the position shift or focus shift correction value has already been set up in the recipe by the method that was explained in the embodiment 1.

The operator inputs the initial values of the inspection condition, such as sample information and recipe, to the memory of the control unit 14 from the interface unit 15 (at Step 1401) and loads a semiconductor wafer that is the sample (Step 1402), followed by execution of pre-charging which irradiates electrons onto a surface of the sample when the need arises (Step 1403). Next, if a voltage distribution of the sample surface is measured and it is judged that the influence by the electron beam falls within an allowable range (Step 1404) by a method as will be described later, then perform calibration of the electron beam (Step 1405). In addition, alignment is performed for determining the point of origin of coordinates of the sample (Step 1406); then, the electron beam is actually irradiated to thereby capture an image, followed by execution of brightness contrast calibration of the image (Step 1407). When the brightness and contrast of the image are judged to fall within the allowable range (Step 1408), actual inspection is executed (Step 1409). By saving and outputting an inspection result, the inspection is completed (Step 1410).

At Step 1404, when the voltage distribution is out of the allowable range, the pre-charging step is repeated up to the second-time verification; however, in case it is out of the allowable range in the third verification, the procedure is ended without performing the inspection because it is presumed that the sample is in the state incapable of performing the inspection. For the inspection of a semiconductor wafer with a similar structure, its inspection is performed after having called out the inspection condition that has been registered in the way stated above; thereby there is no need for newly generating inspection conditions in units of respective semiconductor wafers, thus making it possible to shorten the inspection time.

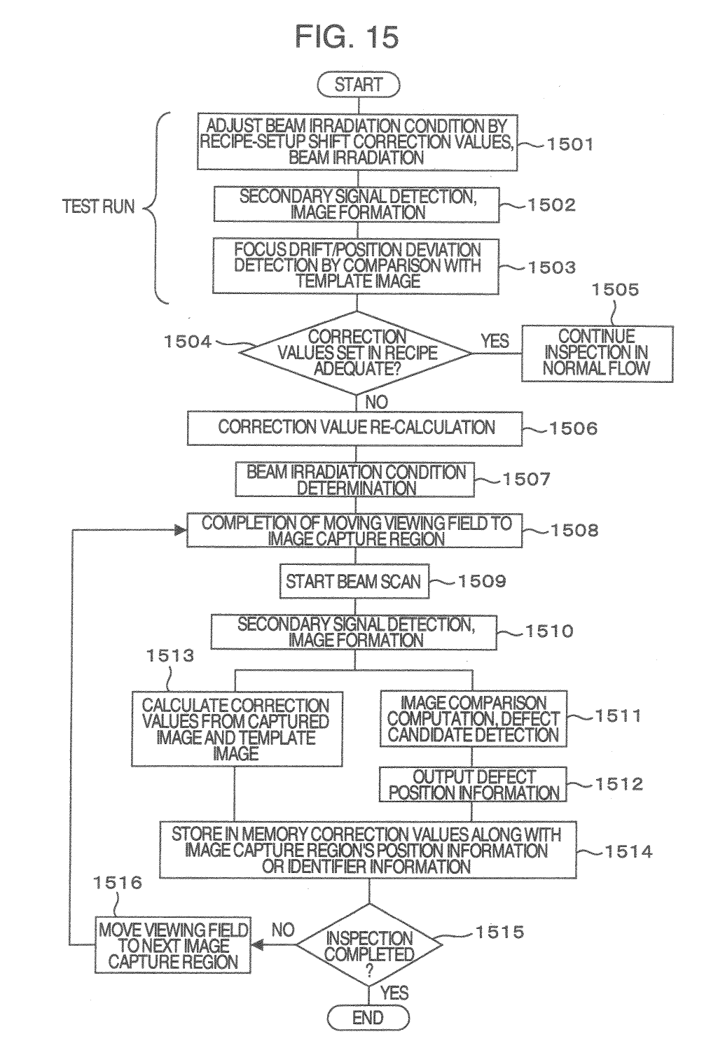

Next, by using FIG. 15, a detailed explanation will be given of performing control of the primary electron beam while recalculating the position shift or focus shift correction values during inspection.

First of all, a test run is executed prior to execution of main inspection. On the occasion of the test run, the inspection condition set up in a recipe is read out, followed by adjustment of the primary electron beam's irradiation position and focusing condition based on the shift amount correction values set up in the recipe. Then, the adjusted beam irradiation condition is used to irradiate the primary electron beam onto an appropriate region (e.g., a single scan stripe, a die at outer wafer periphery, or the like) on the wafer (Step 1501). As a matter of convenience for comparison with a template image (to be described later), it is required that the irradiation region in which the primary electron beam is irradiated at Step 1501 is set in such a manner as to contain at least a region at which the template image was captured.

Thereafter, by detection of secondary particles produced, a secondary, charged particle signal is output from a detector, resulting in formation of an image (Step 1502). Here, in the memory 129 within the image processing unit 13, the image that was used to calculate the position shift and focus shift correction values at the time of setting the recipe is registered as a template. Consequently, the dictionary comparison unit 130 extracts a necessary region (the region that is the same as the template image) from the image captured at Step 1502, and then compares it to the registered template image, thereby calculating a position deviation amount or focus drift amount (Step 1503). From the limit of the capacity of memory 129, only one part of the image used for inspection is saved as the template image, such as the image of a die corner or else, for example. If it is image data like die corners, it is possible to store data concerning all dies on the wafer in the memory 129.

After the position deviation amount or the focus drift amount is calculated, the dictionary comparison unit 130 compares the calculated position deviation amount or focus drift amount with an appropriate threshold value to thereby perform judgment as to whether the position shift or focus shift correction value set in the recipe is adequate or not (Step 1504). The threshold for judgment is stored in the database 131 or in an internal register in the dictionary comparison unit 130 or else.

Once the correction values set in the recipe is determined to be adequate, the main inspection is continued thereafter in a normal flow (Step 1505). When the correction values are judged to be inadequate, a position shift or focus shift correction value is re-calculated (at Step 1506) based on the position deviation amount or the focus drift amount that was calculated at Step 1503. Thereafter, the primary electron beam's irradiation condition is re-adjusted based on the re-calculated correction value (Step 1507); then, the wafer stage is moved, thereby causing the viewing field of the electron optical column to move up to the image capture start position in the main inspection event (Step 1508).

Then, in a similar way to normal inspection flow, there are executed primary electron beam scan processing with respect to a prespecified view-field region (at Step 1509), secondary signal detection and image forming processing by secondary, charged particle detection (Step 1510), defect candidate position detection processing by comparison calculation with respect to a captured image (Step 1511), and processing for outputting coordinate information of a defect candidate position to an externally provided defect database which is not depicted (Step 1512).

In concurrence with the above-stated defect detection flow, a recalculation flow of the a position shift or focus shift correction value is also executed. More specifically, upon capture of the image of a certain view field region (such as a die or a cell) at Step 1510, a position shift or focus shift correction value is calculated by comparison of the captured image with the template image (Step 1513); then, it is stored in either the memory 129 or the database 131 along with the position information of a die or cell (alternatively, identifier information such as a die number) (Step 1514).

Note here that in this embodiment the recalculated a position shift or focus shift correction value will be used for adjustment of beam irradiation conditions of either neighboring dies or adjacent cells because of the fact that the stage is moving continuously and that any process of capturing an image again by returning to the once-image-captured region due to a requirement of throughputs. This is based on the assumption that a neighboring die or adjacent cell must not be extremely changed in charge-up conditions from the present primary electron beam irradiation region.

Subsequently, at Step 1515, a decision is made as to whether the inspection of the last die is completed or not. If it is completed, the main inspection ends. If the inspection is not completed yet, moving to the next view field region is performed by stage movement (Step 1516). Note that in reality the X-Y stage holding thereon the wafer is moving continuously so that the “view field movement” performed at the Step 1508 and Step 1516 means that the control unit 14 determines the scan start timing of the primary electron beam from the stage moving velocity. Obviously, it is also possible to perform the inspection by moving the X-Y stage in a step-and-repeat manner.

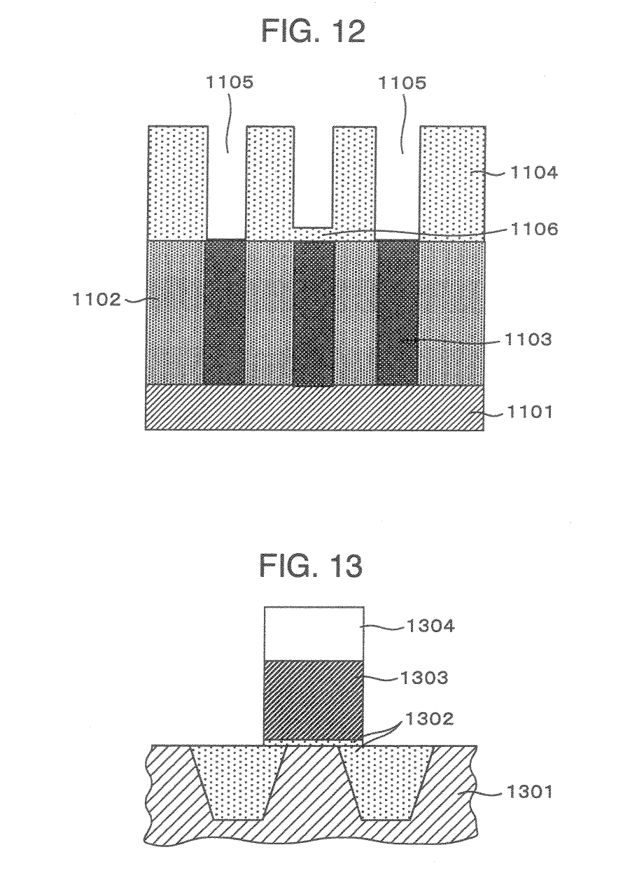

Next, relating to semiconductor devices having the structure as has been explained with reference to FIG. 11, FIG. 12, and FIG. 13, a result of evaluation of the degree of focus drift during inspection will be described below.

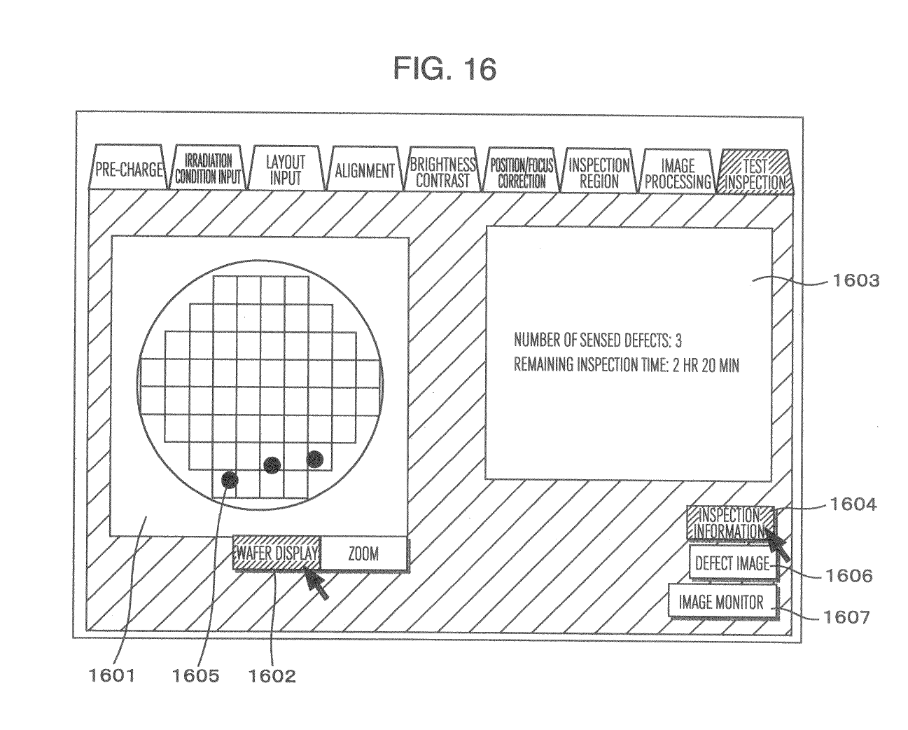

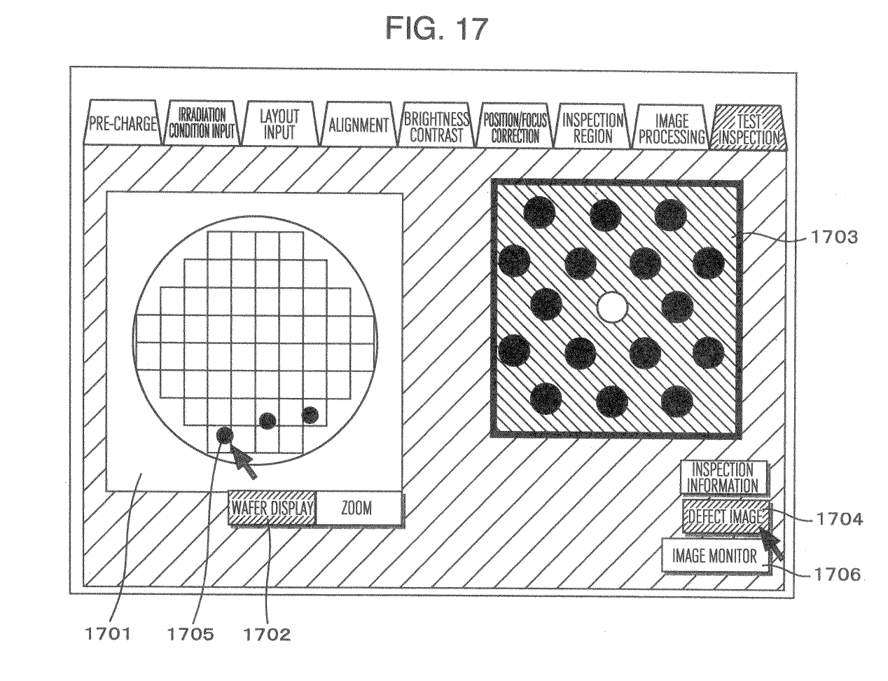

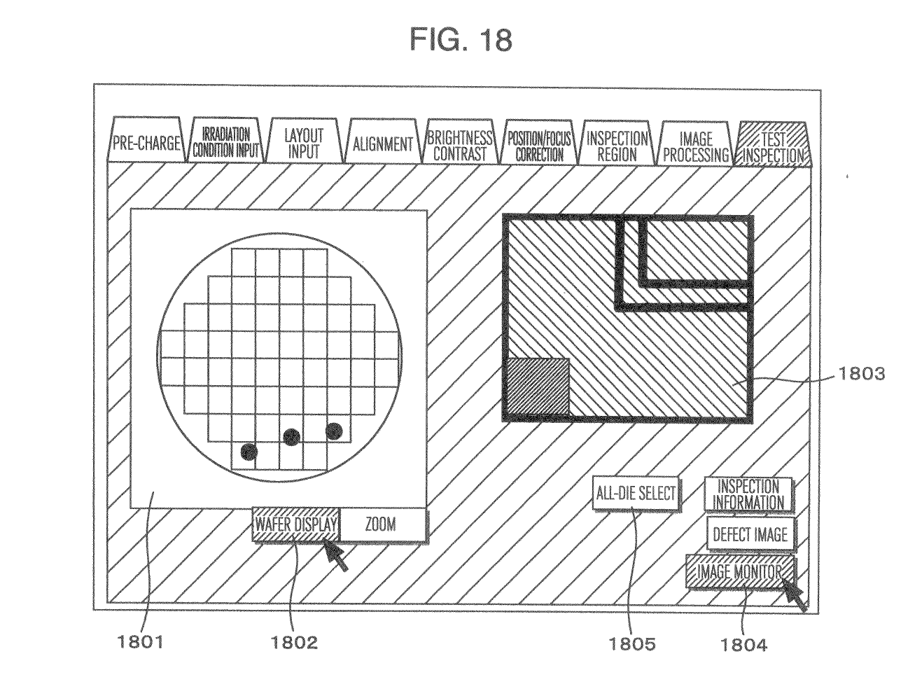

FIG. 16, FIG. 17, and FIG. 18 are screen diagrams showing one example of an image during inspection to be displayed on the screen of a display. In a similar manner to FIG. 7, a schematic diagram 1601, 1701, and 1801 of a plan view of semiconductor wafer is being displayed on the left side by clicking on a tab 1602, 1702, and 1802. On the right side of FIG. 16, there is an inspection information display area 1603, on the right side of FIG. 17, there is a defect image display area 1703, and on the right side of FIG. 18, there is a position/focus correction-use image display area 1803. These are changeable in display contents by depressing an inspection information button 1604, defect image button 1704, or image monitor button 1607, 1706.

Using the position shift correction amount and focus shift correction amount explained in FIG. 7, inspection is executed. During the inspection, a position that is judged to be the defect candidate is displayed as dots 1605 and 1705 on the semiconductor wafer plan-view schematic diagrams 1601 and 1701. In FIG. 16, three dots 1605 are displayed in semiconductor wafer plan-view schematic diagram 1601; in the inspection information display area 1603, the number “3” of detected defect candidates and a remaining time of the inspection are displayed. When pushing a defect image button 1606 after having located a pointer at a dot 1605 that is displayed on the semiconductor wafer plan-view schematic diagram 1601, an image of defect candidates is displayed in the defect image display area 1703 as shown in FIG. 17. When moving the pointer being placed at the dot 1705 to locate it at another dot or, alternatively, clicking thereon in the state that the defect image buttons 1606 or 1704 is depressed, an image corresponding to such a dot is displayed. While letting the pointer be at positions other than the dots, those images of sensed defect candidates are sequentially displayed.

FIG. 18 shows a display when an image monitor button 1804 is depressed, wherein the image 701 that was captured in FIG. 7 or FIG. 8 is displayed in the position/focus correction-use image display area 1803. In this way, during the inspection, it is possible to display an image of the same coordinates for each die without regard to the presence or absence of defect candidates; thus, it is possible for the operator to confirm effects of the position shift correction computation and the focus shift correction computation, thereby making it possible to verify whether the setup condition is good or not. Even when no defect candidates are detected, it is possible to check the focus drift and the position deviation even during the inspection.

As the above, with the inspection apparatus of this embodiment, the inspection apparatus capable of minimizing degradation of image quality occurring due to the focus shift and/or position shift is realized even when inspecting a wafer with the warpage state and the charge-up voltage distribution state out of the conditions presumed in the recipe.

### Embodiment 3

In this embodiment, a modified example of the embodiment 1 will be explained. Entire apparatus configuration and recipe setup flow are almost the same as those of the embodiment 1 and FIG. 1 or FIG. 2 will be arbitrarily used in the explanation below. Additionally, in a similar manner to the embodiment 2, the same explanation as to the reused drawing(s) will not be repeated herein.

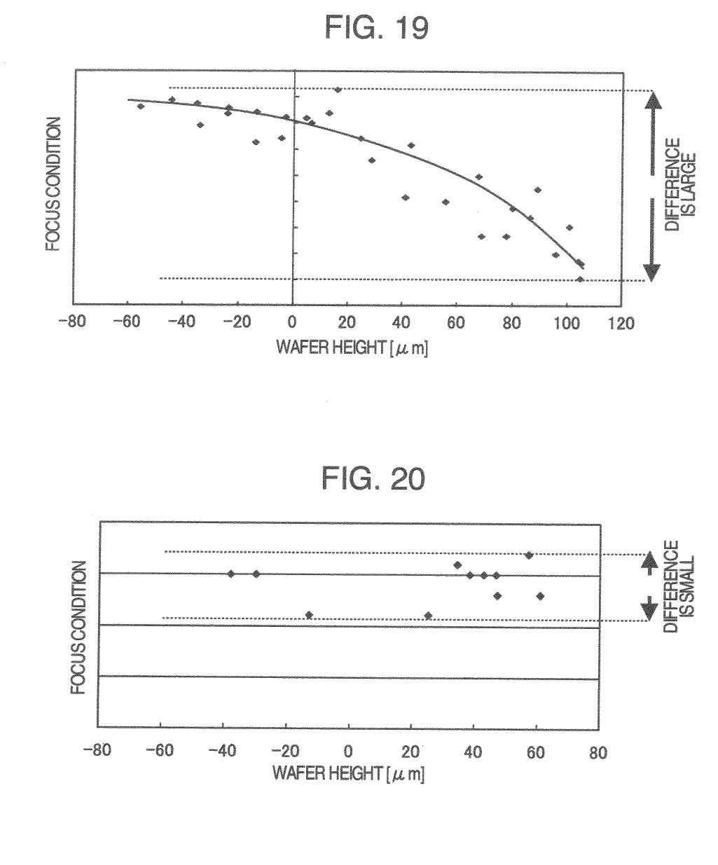

FIG. 19 and FIG. 20 are graphs showing the relationships of semiconductor wafer surface height measurement values measured by a height sensor and focus conditions. FIG. 19 is in the case of a semiconductor wafer at the contact-hole step shown in FIG. 11 or FIG. 12 whereas FIG. 20 is in the case of a semiconductor wafer at the wiring step shown in FIG. 13. They indicate electrical currents of the objective lens at the focusing condition as the focus condition of the vertical axis. When the structure of a semiconductor wafer is easily affected by charge-up, FIG. 19 indicates that the focus can drift unless the excitation intensity of the objective lens is changed depending upon the semiconductor wafer's surface height. In contrast, when the semiconductor wafer structure is hardly affected by the charge-up, FIG. 20 indicates that there is no need to change the excitation intensity of the objective lens even when the semiconductor wafer's surface height is varied.

In this way, the tendency of charge-up influence is different depending upon the structure of a semiconductor wafer; thus, it can be seen that the charge-up state varies with a change in pre-charge conditions and electron beam's optical conditions. One remedy therefore is to obtain in setting up the inspection recipe the relationship between a semiconductor wafer surface height and excitation intensity of the objective lens in terms of the focus with respect to each semiconductor wafer structure and then register a correction value(s). By doing so, it is possible to perform problem-free inspection of the same conditions on other semiconductor wafers as far as at the same fabrication step.

For example, in FIG. 19, there is a correlation between the wafer height and the focus condition; so, a correlation coefficient of the height and focusing condition is obtained, followed by additional amendment of this correction coefficient to the excitation intensity of a focusing-use objective lens on a real-time basis. When there is no correlation with the height as in FIG. 20, a map of focusing conditions obtained at respective dies is produced, wherein an interpolated value is applied between dots thereof.

As a result, it becomes unnecessary to generate the inspection recipe per semiconductor wafer; thus, it is possible to shorten the inspection time.

Since the focus drift tends to take place especially at portions adjacent to the outer periphery of a semiconductor wafer, it is possible to perform correction of focus drift at semiconductor wafer's outer periphery by designating a plurality of dies at outer peripheral portions, obtaining the correlation graph shown in FIG. 19, and registering the correction value at the time of inspection recipe setup. Regarding position deviation also, similar concept is employed to register a correction value in the inspection recipe setup, thereby making it possible to inspect, without problems, other semiconductor wafers under the same inspection condition as long as at the same fabrication step.

Depending on apparatuses there are cases when the focus control includes changing the excitation intensity of the condenser lens in addition to that of the objective lens, the same effects can be obtained by use of the concept of obtaining the correlation graph shown in FIG. 19.

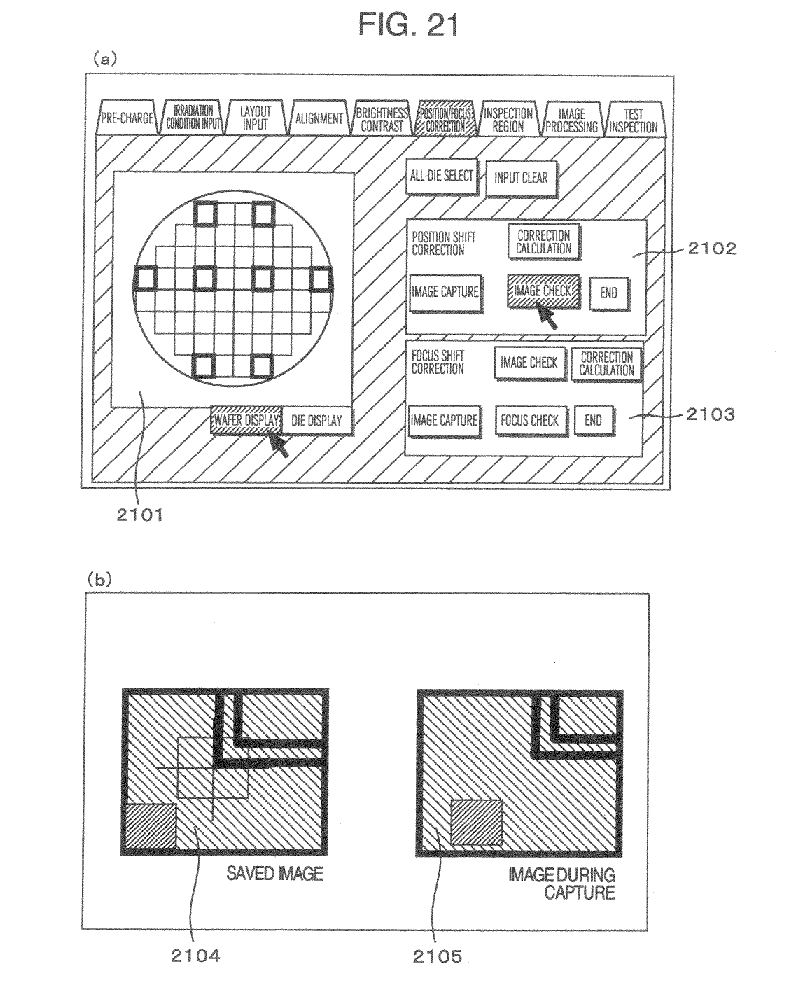

FIG. 21 is a screen diagram showing one example of an image at the time of position/focus correction, which is displayed on a display screen. On the left side of the screen shown in FIG. 21(a), a schematic diagram 2101 of a plan view of semiconductor wafer is displayed; on the right side thereof, a position shift correction menu area 2102 and focus shift correction menu area 2103 are displayed. Displayed on a screen shown in FIG. 21(b) are images that are extracted from the screen shown in FIG. 7. These images are an image 2104 which was captured and stored at the time of the position/focus correction and an image 2105 that was re-captured at the time of either the test inspection or inspection, wherein only one may be displayed or both of them may be displayed in a side-by-side layout manner. By arranging it to display only images on a single screen, each image can be displayed in a magnified form; so, the operator can easily view, resulting in improvement of the usability.

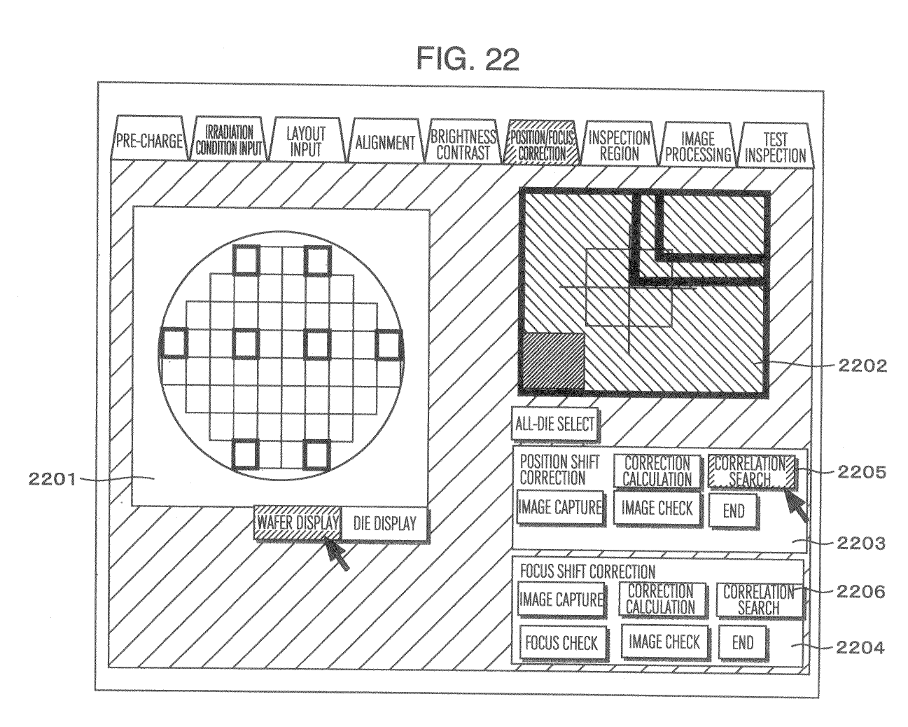

FIG. 22 is a screen diagram showing one example of an image at the time of position/focus correction, which is displayed on the display screen. On the left side, a schematic diagram 2201 of a plan view of semiconductor wafer is displayed; on the right side thereof, an captured position/focus shift correction-use image display area 2202 is displayed with a position shift correction menu area 2203 and focus shift correction menu area 2204 being also displayed. A difference from the embodiment shown in FIG. 7 is that a correlation search button 2205 is provided in the position shift correction menu area 2203 whereas a correlation search button 2206 is provided in the focus shift correction menu area 2204.

In the above-stated embodiments, the method has been explained for correcting position deviation and the focus drift at a limited number of positions selected by the operator such as die corners. In view of the possibility that a semiconductor wafer has its central portion higher than outer peripheral portions, a correction method can be considered in which a height distribution on an entire surface of semiconductor wafer is measured by the height sensor and a measurement result is transmitted to the control unit 14 to reflect on the correction of position deviation and focus drift. By depressing the correlation search button 2205 of the position shift correction menu area 2203 shown in FIG. 22, the height distribution on the entire surface of the semiconductor wafer is reflected on the correction value of position deviation. In addition, by pushing the correlation search button 2206 of the focus shift correction menu area 2204, the height distribution on the entire surface of semiconductor wafer is reflected on the focus drift correction value.

According to the invention as described in each embodiment stated above, when inspecting under the same inspection condition those products of the same specification or semiconductor wafers at the same fabrication step, it becomes possible, by correcting an charge-up state which is different per kind of semiconductor wafers and per inspection conditions and registering to the inspection recipes in a way pursuant to principles of this invention, to implement the inspection in a state that there are no position deviation or focus drift in the semiconductor wafer surface plane without having to spend a lot of time to perform the correction on a per-inspection basis. Additionally, it becomes possible, for samples susceptible to charge up such as semiconductor wafers, to perform the inspection with the same sensitivity at any portions on the semiconductor wafer surface; thus, it is possible to suppress false detection of defect candidates at the outer periphery of semiconductor wafers and deterioration of inspection sensitivity so that it becomes possible to achieve stable inspection and to improve reliability of the inspection.

As the above, by providing the technology for performing inspection with high-sensitivity and high-accuracy in semiconductor device fabrication processes, it is possible to quickly detect the contents of a defect(s) at important steps in a fabrication process and also possible to obtain the information of a defect position and size which is necessary for implementation of a remedy at the same time as execution of the inspection; thus, it is possible to shorten the length of a time up to taking corrective actions, resulting in improvement of fabrication yield of semiconductor devices and enhancement of the productivity thereof.

### REFERENCE SIGNS LIST

11 Electron Beam
12 Secondary Particles
13 Image Processing Unit
14 Control Unit
15 Interface Unit
110 Objective Lens
111, 112 Electrode
113 Detector
114 Amplifier
115 AD Converter
116 Pre-charge Unit
117, 118 Image Memory
119 Comparison Calculation Unit
120 Defect Determination Unit
121 Display
123, 302 Sample
124 X-Stage
125 Y-Stage
127 Height Sensor
128 Retarding Power Supply
129 Memory
130 Dictionary Comparison Unit
131 Database
303 Piece A
304 Piece B
305 Piece C
601 Magnified Image
602, 901, 1001 Semiconductor Wafer
603 Die Corner
701 Image
702, 2102, 2203 Position Shift Correction Menu Area
703, 2103, 2204 Focus Shift Correction Menu Area
1803, 2202 Position/Focus Correction-Use Image Display Area

1. An electron beam apparatus for irradiating a primary electron beam onto a semiconductor wafer having a plurality of dies with patterns formed thereon under a condition satisfying an inspection recipe describing a prespecified inspection condition and for detecting and imaging secondary particles to be generated from the sample to thereby detect a defect candidate of said sample, wherein comprising:
an electron beam column for scanning said primary electron beam with respect to said semiconductor wafer, for detecting said secondary particles to be generated due to said scanning and for outputting said secondary particles as a secondary signal;
a sample stage holding thereon said semiconductor wafer and moving said semiconductor wafer in a predetermined direction within an X-Y plane;
an image processing device for executing, at a time of generating said inspection recipe, wafer alignment from an image of an alignment mark on said semiconductor wafer to thereby determine a point of origin of a coordinate system for use in irradiation position control of said primary electron beam, and further for comparing, in regard to images of predefined regions within a plurality of dies on said semiconductor wafer to be obtained with respect to said dies, one image of the images of said predefined regions with an image of said predefined region in relation to another die while letting said one image be a reference image to thereby calculate a correction value of a position deviation amount of an irradiation position of said primary electron beam;
a memory means for storing therein said calculated position deviation correction value as said inspection recipe; and
a control unit for controlling, during inspection of said semiconductor wafer, the irradiation position of said primary electron beam based on the correction value of a position deviation amount being stored as said inspection recipe.

2. The electron beam apparatus as recited in claim 1, wherein;
at the time of generating said inspection recipe,
said control unit sets up on said semiconductor wafer a plurality of scan stripes containing therein said predefined regions and controls said electron optical column in such a manner that said primary electron beam is scanned on said scan stripes; and
said image processing device extracts the images of said predefined regions from an image of said scan stripes and calculates correction value of said position deviation amount.

3. The electron beam apparatus as recited in claim 2, further comprising
image display means for displaying a region setup screen for setup of said predefined regions and said reference region on the image of said dies.

4. The electron beam apparatus as recited in claim 3, wherein
said image processing device executes said extraction processing by expanding position information of said predefined regions and said reference region, which are set up on said region setup screen, to all dies included in said scan stripes.

5. The electron beam apparatus as recited in claim 1, wherein
at the time of generating said inspection recipe,
said image processing device calculates focusing conditions from an image to be obtained by irradiation of said primary electron beam onto said plurality of dies, and
uses one focusing condition of said calculated focusing conditions for said plurality of dies as a reference to obtain a difference between said reference focusing condition and another focusing condition to thereby calculate a correction value of a focus drift amount in the plane on said semiconductor wafer.

6. The electron beam apparatus as recited in claim 5, wherein
during calculation of the correction value of said focus drift amount,
said control unit controls said electron optical column in such a way as to capture a plurality of images of different focusing positions with respect to said predefined regions and said reference region.

7. The electron beam apparatus as recited in claim 5, wherein
further comprising a plurality of focus adjustment pieces for use in focus adjustment of irradiation of said primary electron beam prior to capture of the images of said plurality of dies.

8. The electron beam apparatus as recited in claim 6, wherein
said control unit
causes, during calculation of the correction value of said position deviation amount, said X-Y stage to move continuously in a direction crossing the scan direction of said primary electron beam and,
during calculation of the correction value of said focus drift amount,
makes said X-Y stage move to existence positions of said plurality of dies in a step-and-repeat manner.

9. The electron beam apparatus as recited in claim 1, wherein
further comprising a pre-charge unit to irradiate pre-charging electrons onto said dies.

10. A method for generating an inspection recipe used to perform inspection of a semiconductor wafer having one or more pattern-formed dies under a predetermined inspection condition, wherein
said inspection recipe generation method is used by an electron beam apparatus which performs said inspection by using an image obtained by irradiation of a primary electron beam onto said semiconductor wafer being held on an X-Y stage and that the method comprises:
executing wafer alignment to thereby determine a point of origin of a coordinate system used for irradiation position control of said primary electron beam;
setting, inside said dies, a region for capture of an image necessary to execute irradiation position deviation correction of said primary electron beam;
capturing an image of said region for a plurality of dies;
using one image of said captured images with respect to the plurality of dies as a reference image to compare said reference image with other images to thereby calculate a correction value of a position deviation amount of an irradiation position of said primary electron beam; and
memorizing said calculated position deviation correction value as said inspection recipe.

11. The inspection recipe generation method as recited in claim 10, wherein further comprising:
executing focus adjustment of said primary electron beam on a focus adjustment piece;
capturing a plurality of images of a different focusing positions with respect to said plurality of dies, thereby obtaining focusing conditions of irradiation of said primary electron beam with respect to said setup regions;
using one focusing condition of said captured focusing conditions for the plurality of dies as a reference to obtain differences between said reference focusing condition and other focusing conditions to thereby calculate a correction value of a focus drift amount dependent on positions on said semiconductor wafer; and
memorizing the calculated correction value of the focus drift amount as said inspection recipe.

12. The inspection recipe generation method as recited in claim 11, wherein further comprising:
setting, at a time of calculating the correction value of said position deviation amount, a scan stripe containing said regions with respect to all dies on said semiconductor wafer to capture images of the said setup regions for said all dies; and
at a time of calculating the correction value of said focus drift amount, calculating focusing conditions with respect to a plurality of dies as intermittently set up on said semiconductor wafer.

13. The inspection recipe setup method as recited in claim 12, wherein further comprising:
causing said X-Y stage to move continuously at the time of calculating the correction value of said position deviation amount; and
causing said X-Y stage to move in a step-and-repeat manner at the time of calculating the correction value of said focus drift amount.
